(19) United States
(12) Patent Application Publication
(10) Pub. No.: US 2004/0066207 A1
(43) Pub. Date: Apr. 8, 2004

(54) Flexible DUT interface assembly

(76) Inventors: Wilmer R. Bottoms, Palo Alto, CA (US); Cran D. Cowan, Sunnyvale, CA (US)

Correspondence Address: NGUYEN & ASSOCIATES, Suite #171, 50 Airport Parkway, San Jose, CA, 95110, US

(21) Appl. No.: 10/265,549

(22) Filed: Oct. 5, 2002

(51) Int. Cl. G01R 31/02

(52) U.S. Cl. 324/754

(57) ABSTRACT

A flexible DUT interface assembly is presented. The DUT interface assembly includes a DUT interface board with a plurality of slots to accommodate inserted circuit cards for providing a plurality of different test functions, a socket adapter card to accommodate a plurality of DUTs via a plurality of sockets and to provide the interface between the DUTs and the DUT interface board, and an interposer to provide the required space for the inserted circuit cards between the DUT interface board and a test head module. The modular characteristics of the assembly parts (i.e., DUT interface board, socket adapter, and interposer) and their sub-components allows configuration (e.g., DUTs, test functions, etc.) and repair to be rapidly and easily carried out. The interposer allows external environmental factors around close-coupled instruments, such as temperature, humidity, and electrical noise, to be easily monitored and controlled. Moreover, the interposer effectively shifts the loading associated with attaching and detaching the DUT interface board to/from the test head module away from the test head module itself so that damages on the test head module associated with such loading are minimized during set up. Finally, the DUT interface board assembly of the present invention allows close-coupled instruments to be located in the DUTs proximity which helps to reduce signal radiation, to improve signal-to-noise ratio, and to reduce transmission losses.

### FIELD OF THE INVENTION

The invention relates generally to Automatic Test Equipments (ATEs), and more particularly to a flexible architecture to provide the interface between a Device Under Test (DUT) and specialized instrumentation during testing by an ATE.

### BACKGROUND OF THE INVENTION

To provide quality assurance, semiconductor device makers systematically perform tests on their products to ensure that they meet or exceed all of their design parameters. Some of the types of tests routinely performed include device parametric testing, device logic function testing, and device timing testing. The semiconductor device being tested is commonly known as the Device Under Test (DUT) and the test system used in conducting the above tests on the DUT is commonly known as Automatic Test Equipment (ATE). In carrying out the aforementioned tests on very sensitive DUTs, the ATE is necessarily very precise. In general, the ATE hardware is controlled by a computer which executes a test program to present the correct voltages, currents, timings, and functional states to the DUT and measure the response from the DUT for each test. The result of each test is then compared to pre-defined limits and a pass/fail decision is made. As such, the ATE hardware normally includes a collection of power-supplies, meters, signal generators, pattern generators, etc.

In a typical ATE, a control computer including display, power supplies, I/O peripherals (e.g., data storage drives, printers), and some instrumentation are mounted in a rack console. The ATE has a remote test head module which carries those instrument cards that need to be in close proximity to the DUT. These instrument cards are designed to provide voltages, currents, timings, and functional states to the DUT and to measure the responses. A cable links the remote test head module to the equipments in the rack console to supply power from the rack console to the remote test head module as well as to allow the transfer of data and control/command signals between the rack console and the remote test head module. During testing, the remote test head module is stabilized in place by a test fixture. The remote test head module is then attached directly to a DUT interface board which is used to hold the DUT, to provide an interface between the DUT and the remote test head module, and to position the DUT relative to the remote test head module.

FIG. 1 illustrates a side view of a prior art DUT interface board (with a DUT) attached to a remote test head module. As shown, DUT interface board 102, which may be a simple circuit board, is attached to test head module 101 (shown partially) through matching connectors 103 on one side and attached to DUT 104 on the other side. Instead of using matching connector 103, DUT interface board 102 may be attached to test head module 101 using a clamping fixture together with pogo pins that are spring-loaded to ensure firm electrical contacts between test head module 101 and DUT interface board 102.

In attaching DUT interface board 102 directly to test head module 101, damage may occur, for example to connectors 103 or pogo pins and/or test head module 102, during the repeated attachment and detachment process. When such mishaps (e.g., use of excessive force and/or misalignment) occur, at least a portion of the test head module must be repaired or replaced which requires the ATE use to be shut down for service. In general, any type of ATE shutdown is totally undesirable for the simple reason that devices cannot be tested causing schedules to slip and resources such as facility and labor to sit idle.

In its simplest form, DUT interface board 102 may be nothing more than a circuit board with connectors to allow a DUT to be plugged in and to allow the DUT interface board to be mechanically and electrically connected to the test head. By adding electrical components 105 such as capacitors, resistors, diodes, etc. on DUT interface board 102, a DUT interface board may be customized to perform a specific test function which requires close-coupling between the DUT and these specialized test circuit elements. Due to the size constraint of the circuit board, the DUT interface board is generally limited to performing only a single specific test function for only one DUT at any time. This significantly reduces the test throughput and test capacity when testing large number of DUTs that require different test functions. This is because only one DUT can only be tested using only one test function at any one time. Many electronic products today have a short life cycle and time to market is a critical economic factor. The traditional design and manufacture approach of using specialized DUT interface boards delays time to market and adds significantly to testing cost.

Because DUTs are very sensitive electronic devices, the testing circuits used in taking ATE measurements must be able to accommodate a wide range of sensitivity, resolution, and accuracy requirements. However, the sensitivity, resolution, and accuracy of testing circuits are adversely affected by external environmental factors such as temperature and humidity.

As computers and testers move into the gigahertz range, corresponding wavelengths are a few millimeters. At such wavelengths, almost any wire is an antenna causing signal radiation. Also, ATEs are now working with lower power levels, with currents in the microampere range. This increases the effects of electrical noise. Where higher powers are used to offset noise, transmission line losses occur thereby reducing efficiency.

Thus, a need exists for an architecture that can reduce time to market and reduce test cost, accommodate a plurality of DUTs for testing at any one time, easily and rapidly be configured to provide a plurality of different test functions to the plurality of DUTs at any one time, minimize damages to the test head module and its connectors during set up, and control external environmental factors which may adversely effect test functions carried out on a DUT interface board. At the same time, such DUT interface board improvement needs to address concerns regarding signal radiation, signal-to-noise ratio, as well as transmission line losses.

### SUMMARY OF THE INVENTION

Accordingly, the present invention provides an architecture incorporating a DUT interface board assembly that can accommodate a plurality of DUTs for testing at any one time, can easily and rapidly be configured to provide a plurality of different test functions to the plurality of DUTs at any one time while maintaining the instrument circuitry required for the test functions in the DUT proximity, minimize damages to the test head module and its connectors during set up, control external environmental factors which may adversely effect test functions carried out by the DUT interface board, and allow close-coupled instruments to be located in the DUTs proximity to eliminate the requirement for specialized instrumentation on the DUT interface board, reduce signal radiation, improve signal-to-noise ratio, and reduce transmission line losses.

The present invention meets the above objectives with a Device-Under-Test (DUT) interface board assembly that provides the interface between DUTs, close-coupled instruments, and a test head of an ATE system. The ATE system may be a typical ATE system having a Central Processing Unit (CPU), Input/Output (I/O) peripherals connected to the CPU, and a test head electrically linked to the CPU.

The invention comprises: a DUT interface boardand an interposer. The invention may further include a socket adapter. The DUT interface board has one or more receptacles to receive one or more close-coupled instruments wherein each board is made up of electrical components designed to perform a specific test function. In so doing, the DUT interface board can accommodate a variety of instruments requiring close proximity to the DUT. The one or more receptacles provide an electrical connection between the DUT interface board and the one or more close-coupled instruments. The close-coupled instruments boards are detachable from the DUT interface board to enable rapid reconfiguration of the test setup.

The interposer is mechanically and electrically connected between the test head and the DUT interface board. The interposer has a cavity to spatially accommodate the plurality of close-coupled instruments inserted into the slots on the DUT interface board. When the interposer is attached between the test head and the DUT interface board, the cavity becomes essentially enclosed thereby facilitating controlling of environmental factors inside the enclosed cavity. The DUT interface board is detachable from the interposerwhich is desirable because any attachment/detachment involving the test head module is limited to instances of necessity. In so doing, damage to the test head module and wear-and-tear to the test head module connectors are minimized such that their life cycles can be prolonged.

The socket adapter is mechanically and electrically connected to the DUT interface board. The socket adapter is detachable from the DUT interface board. The socket adapter has a plurality of receptacles to connect a plurality of sockets. The socket adapter provides an electrical connection between the plurality of sockets and the DUT interface board. The plurality of sockets receives the plurality of DUTs such that the DUTs are located in the proximity of the close-coupled instruments boards. The plurality of sockets provides an electrical connection between the plurality of DUTs and the socket adapter. In so doing, a multiplicity of DUTs can be tested with a multiplicity of test functions at the same time thereby increasing the tester throughput by enabling parallel multi-site testing and reducing time to market and test cost by eliminating the need for a custom DUT interface board for each test setup.

All the features and advantages of the present invention will become apparent from the following detailed description of its preferred embodiment whose description should be taken in conjunction with the accompanying drawings.

### BRIEF DESCRIPTION OF THE DRAWINGS

FIG. 1 illustrates a side view of a prior art DUT interface board (with a DUT) attached to a remote test head module.

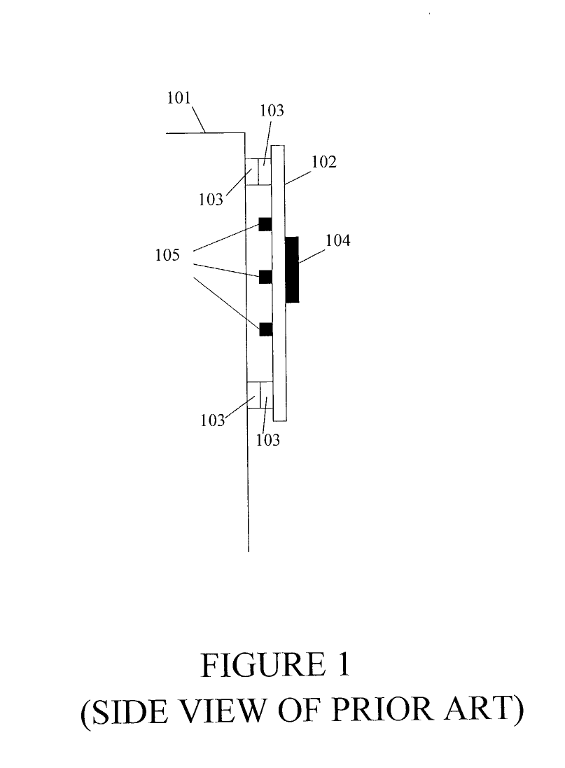

FIG. 2 illustrates a block diagram of an exemplary computer controlled Automatic Test Equipment (ATE) that implements the present invention.

FIG. 3 illustrates a side view of an embodiment of the DUT interface board assembly in accordance with the present invention attached to remote test head module 201.

FIG. 4 illustrates in greater detail an iso-view of an embodiment of interposer 302 in accordance with the present invention.

FIG. 5A illustrates an exemplary front view of an embodiment of DUT interface board 303 in accordance with the present invention.

FIG. 5B illustrates an exemplary back view of an embodiment of DUT interface board 303.

FIG. 6A illustrates an exemplary front view of an embodiment of socket adapter board 305 in accordance with the present invention.

FIG. 6B illustrates an exemplary back view of an embodiment of socket adapter board 305.

### DETAILED DESCRIPTION OF THE INVENTION

In the following detailed description of the present invention, numerous specific details are set forth in order to provide a thorough understanding of the present invention. However, it will be obvious to one skilled in the art that the present invention may be practiced without these specific details. In other instances, well known methods, procedures, components, and circuits have not been described in detail as not to unnecessarily obscure aspects of the present invention.

In accordance with the present invention, a DUT interface board assembly includes a DUT interface board with a plurality of slots to accommodate inserted close-coupled instruments boards for providing a plurality of different test functions (e.g., feedback loop function, relay matrix function, Built In Self Test (BIST) functions, analog functions, etc.) and an interposer to increase test head connectors life, to allow electrical functions such as signal conditioning, to accommodate depth requirements of prober/handler mechanical interfaces, to provide the required space for the inserted close-coupled instruments between the DUT interface board and a test head module and to enable control of the temperature, humidity and electrical noise in that space. In addition, a socket adapter card may be further included to accommodate a plurality of DUTs via a plurality of sockets and to provide the interface between the DUTs and the DUT interface board.

The modular characteristics of the assembly parts (i.e., DUT interface board, socket adapter, and interposer) and their sub-components allows configuration (e.g., DUTs, test functions, etc.) and repair to be rapidly and easily carried out. By having slots to allow a number of different close-coupled instruments inserted into DUT interface board at any one time, the DUT interface assembly can be configured easily and rapidly to provide different test functions. The socket adapter has multiple sockets to allow a number of DUTS to be tested by at any one time. As a result, time to market and test cost can be reduced. When the DUT interface board is attached to the test head module via the interposer, the interposer provides not only the required space to accommodate the circuit cards but also an enclosure to allow external environmental factors around these circuit cards, such as temperature, humidity, and electrical noise, to be easily monitored and controlled. Moreover, the interposer effectively shifts the physical load associated with attaching and detaching the DUT interface board to/from the test head module away from the test head module itself so that damages on the test head module and wear-and-tear on its connectors associated with such loading are minimized during set up. Connector life is therefore increased. Additionally, the interposer can be used (perhaps with additional circuitry) as an electrical buffer between two components with different electrical characteristics to provide an electrical signal conditioning function. Furthermore, the prober/handler's physical dimensions require that a certain depth/distance be provided from the DUT to the test head module. This depth/distance can be accommodated by adjusting the height of the interposer. Finally, the DUT interface board assembly of the present invention allows close-coupled instruments to be located in the DUTs proximity which helps to reduce signal radiation, to decrease signal round-trip delay, to improve signal-to-noise ratio, and to reduce transmission losses.

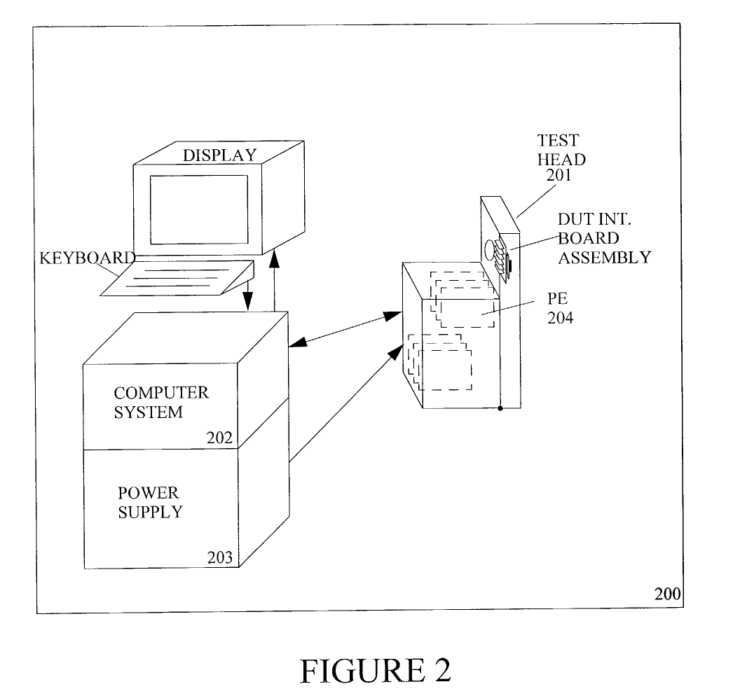

Reference is now made to FIG. 2 illustrating a block diagram of exemplary computer controlled Automatic Test Equipment (ATE) 200 that implements the present invention. ATE 200 comprises remote test head 201, computer system 202, and system power supplies 203. Computer system 202 is the system controller. Computer system 202 controls remote test head 201 which is electrically linked to computer system 202 by an electrical cable. Computer system 202 also acts as a hub to transfer data to/from ATE 200. Hence, computer system 202 may generally include a central processing unit (CPU), input/output (I/O) interfaces such as parallel and serial ports, communications interface for networking and communicating with the outside world, video/graphics controller, a number of data storage devices such as Read Only Memory (ROM), Random Access Memory (RAM), hard drive, and tape drive or other media for locally storing instructions and data, I/O devices such as keyboard and video monitor to allow the operator to interact with ATE 200. It is to be appreciated that computer system 202 can be any one of a number of different computer systems including desk-top computer systems, general purpose computer systems, embedded computer systems, and others. Remote test head 201 carries all the instrument circuitry cards required to generate forced test signals and to measure responded signals from the DUT before sending them to computer system 202 for analysis. Accordingly, remote test head 201 is used to interface with the DUT. The present invention provides the interface between the remote test head 201 and the DUT(s).

Remote test head 201 includes Pin Electronics (PE) circuitry 204 which provides the primary electrical test signals to drive the DUT. More particularly, PE circuitry 204 supplies input signals to the DUT and receives output signals from the DUT. As an example, in parametric testing, either an input voltage is sent to the DUT and an output current is received from the DUT or an input current is sent to the DUT and an output voltage is received from the DUT. System power supplies 203 provide steady and uninterrupted direct current (DC) power to test head 201. Depending on its test purposes, it is to be appreciated that an ATE may have more or fewer than the components discussed above. Further, it should be clear that the components of the ATE discussed above are conventional and well known by people of ordinary skill in the art.

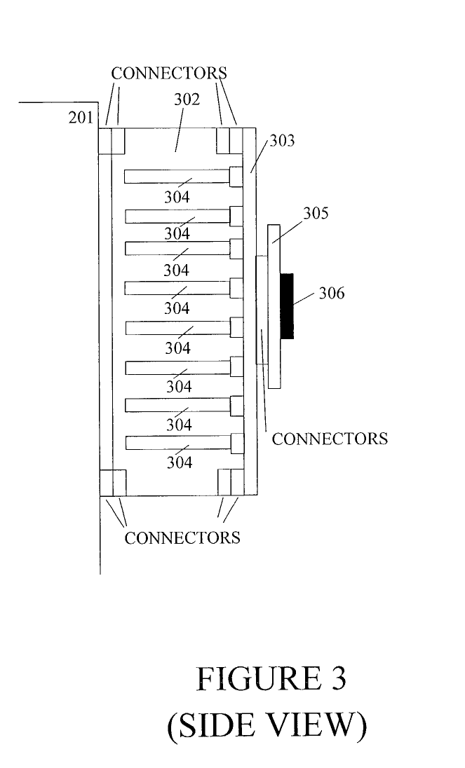

Referring now to FIG. 3 illustrating a side view (with interposer 302 partially exposed) of an embodiment of the DUT interface board assembly attached to remote test head module 201 in accordance with the present invention. As shown in FIG. 3, test head module 201 is attached to interposer 302 which is in turn attached to DUT interface board 303. DUT interface board assembly 303 has a number (eight are shown) of close-coupled instruments boards 304 to provide different test functions attached to it via slots on one side and socket adapter card 305 attached to it via connectors on the other side. Socket adapter card 305 in turn has a plurality of DUTS 306 plugged in. In accordance with the present invention, close-coupled instruments 304 are located in the DUTs proximity to reduce signal radiation, to decrease signal round-trip delay, to improve signal-to-noise ratio, and to reduce transmission losses. Another advantage in having close-coupled instruments 304 is to eliminate the need for specialized circuitry on DUT interface board 303.

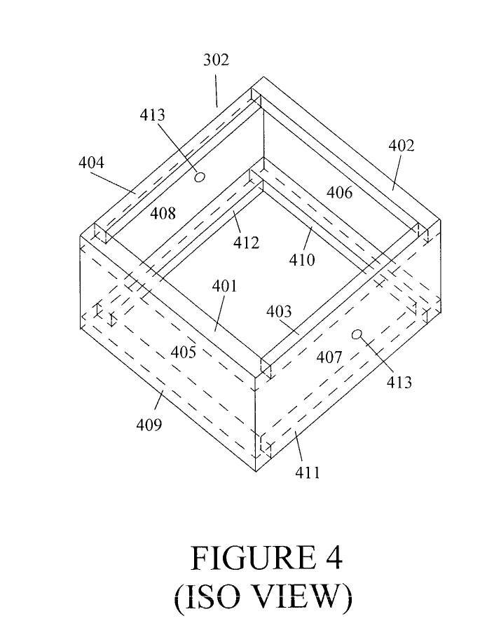

FIG. 4 illustrates in greater detail an iso-view of an embodiment of interposer 302 in accordance with the present invention. As shown in FIG. 4, interposer 302 is an open-ended tubular-like bracket having four adjoined walls with an interior cavity. The cavity is used to provide the required space to accommodate close-coupled instruments 304 when interposer 302 is in its set up position (attached between test head module 201 and DUT interface board 303). Hence, the height of interposer 302 should be long enough to spatially accommodate close-coupled instruments 304 when interposer 302 is attached between test head 201 and DUT interface board 303. Preferably, interposer 302 is made out of aluminum but can also be made out of other materials including composites. In one embodiment, interposer 302 employs four connectors 401-404 at one end of walls 405-408, respectively, to make a mechanical and electrical connection to test head module 201. In another embodiment, interposer 302 employs pogo pins at one end of walls 405-408 to make a mechanical and electrical connection (through the use of a clamping device) to test head module 201. At the opposite end of walls 405-408, interposer 302 employs four connectors 409-412, respectively, to make a mechanical and electrical connection to DUT interface board 303. Because connectors 401-404 are electrically connected to connectors 409-412, electrical signals can be passed from one end of interposer 302 to the other end such that electrical signals from/to the DUT can be sent to/from test head module 201. The height of interposer 302 (i.e., the distance between connectors 401-404 and 409-412) can be of any length required to accommodate the mechanical interface between the ATE and a handler/prober. Interposer 302 may incorporate signal conditioning circuitry (e.g., for buffering different electrical characteristics between test head 201 and the DUTs). Such signal conditioning circuitry is well-known to persons of ordinary skill in the art and is therefore not discussed further here.

In accordance with the present invention, once interposer 302 is attached to test head module 201, interposer 302 remains fixed at this location is not removed from test head module 201 unless it is necessary. In so doing, only DUT interface board 303 needs to be portable. In other words, only DUT interface board 303 needs to be involved in the attachment/detachment process relative to interposer 302 so that the exposure of associated loading/unloading force to test head module 201 is minimized. By minimizing the exposure of loading/unloading force to test head module 201, damages to test head module 201 and its connectors that may occur as a result are significantly reduced. A connector cycle life of test head 201 is extended. Such damages to test head module 201 is undesirable because it can cause the ATE 200 to be shut down for repair which adversely affects production schedules. Connectors and pogo pins discussed above are well-known to persons of ordinary skill in the art and therefore are not further discussed.

In accordance with the present invention, the cavity of interposer 302 is essentially enclosed (i.e., require some minimum effort to seal small openings) when interposer 302 is attached to test head module 201 and DUT interface board 303. Such an enclosure facilitates the ability to create an electrically shielded airtight atmosphere inside the cavity. An electrically shielded airtight atmosphere allows environment factors, such as temperature, humidity, and electrical noise to which close-coupled instruments 304 are exposed, to be more easily controlled. Because very sensitive test function circuitry is required for very sensitive DUTs, the precision and accuracy of test function circuits can be adversely affected by environmental factors. Accordingly, interposer 302 has holes/cutouts 413 in walls 407 and 408 to allow dry air or inert gas to be pumped into its cavity to control the humidity of the air inside its cavity. Holes/cutouts 413 can also be used to allow cool air from an operating external fan attached to wall 407 or wall 408 or inert gas to flow in to control the temperature of the air inside its cavity. An electrically shielded atmosphere provides electrical isolation for noise reduction.

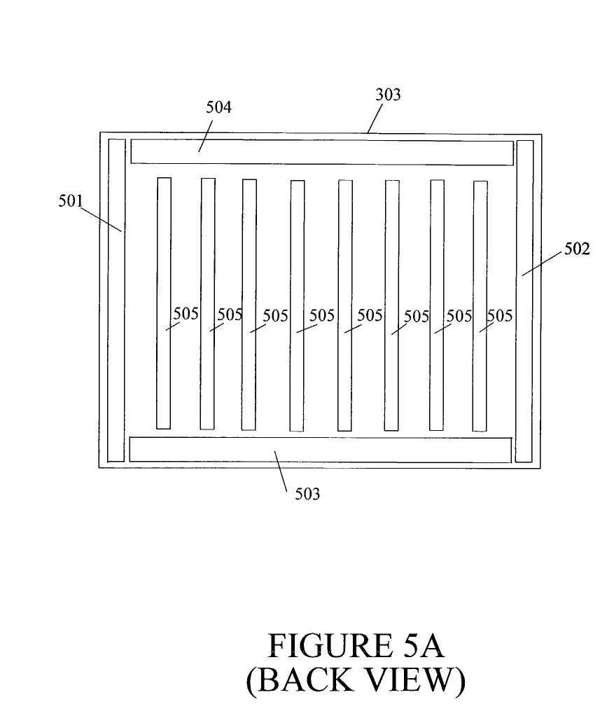

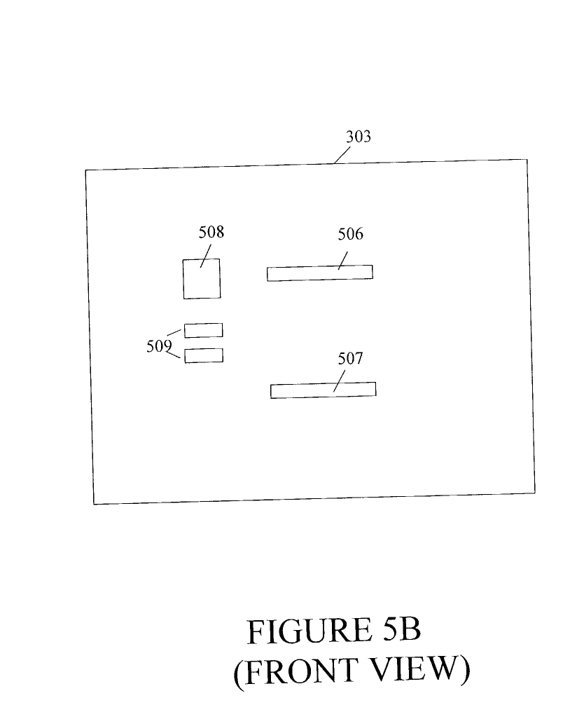

Reference is now made to FIG. 5A illustrating an exemplary back view of an embodiment of DUT interface board 303 in accordance with the present invention. In one embodiment, DUT interface board 303 is a circuit board. As shown in FIG. 5A, in one embodiment of its back side, DUT interface board 303 has four connectors 501-504 which are electrically and mechanically connected to DUT interface board 303. Connectors 501-504 are positioned and designed to correspond and connect to connectors 409-412, respectively, on DUT interface board 303. In other words, DUT interface board 303 can be electrically and mechanically connected to interposer 302 through corresponding connectors 501-504 and 409-412. Hence, electrical signals can be sent between interposer 302 and DUT interface board 303. Additionally, on its front side, DUT interface board 303 has a number (eight are shown) of interface slots 505, which are electrically and mechanically connected to DUT interface board 303, into which close-coupled instruments 304 that are designed to perform different test functions can be easily and rapidly inserted. In so doing, DUT interface board 303 can be configured rapidly and easily (by replacing inserted close-coupled instruments 304 with different ones) to perform different test functions (depending on the type of test) on the DUT at any one time. In other words, each DUT interface board 303 is not limited to just one or a most a few test functions as in the prior art but can be configured to carry out many different test functions. In the current embodiment, slots 505 are positioned parallel to connectors 501 and 502. However, slots 505 can also be positioned in different orientations such as perpendicular to connectors 501 and 502, or both perpendicular and parallel to connectors 501 and 502, and others. In an embodiment, slots 505 are simply connectors. Connectors discussed above are well-known to persons of ordinary skill in the art and therefore are not further discussed. The test functions provided by close-coupled instruments 304, such as feedback loop function, relay matrix function, BIST functions, analog functions, are well-known to persons of ordinary skill in the art. Accordingly, the electrical components and circuitry design required to carry out each of these test functions should be well-known to persons of ordinary skill in the art and are not further discussed.

Referring now to FIG. 5B which illustrates an exemplary front view of an embodiment of DUT interface board 303. As shown in FIG. 5B, in one embodiment of its front view, DUT interface board 303 has two connectors 506-507 positioned in parallel to each other. Other orientations of connectors 506-507 are also within the scope of the invention. Connectors 506-507 are electrically and mechanically connected to DUT interface board 303 such that electrical signals can be sent between connectors 506-507, slots 505, and connectors 501-504. In one embodiment, connectors 506-507 are used to allow socket adapter board 305 in accordance to the present invention to be electrically and mechanically connected to DUT interface board 303. In another embodiment, connectors 506-507 are used to directly accommodate the DUTs thereby bypassing socket adapter board 305. Connectors discussed above are well-known to persons of ordinary skill in the art and therefore are not further discussed.

In one embodiment, DUT interface board 303 includes Complex Programmable Logic Device (CPLD) 508 and memory 509. CPLD 508 is used to configure DUT interface board 303 for a specific test function and to provide local control of close-coupled instruments mounted on boards that are inserted into slots 505. Such a CPLD is well-known to persons of ordinary skill in the art and for this reason is not further discussed. Memory 509 is preferably Electrically Erasable Programmable Read Only Memory (EEPROM) that is used to store configuration parameters for different test functions so that when used together with CPLD 508, a specific test configuration (from many stored ones) can be selected and programmed for DUT interface board 303. Memory 509 also provides local storage of calibration constants, use history, maintenance history, etc. associated with DUT interface board 303.

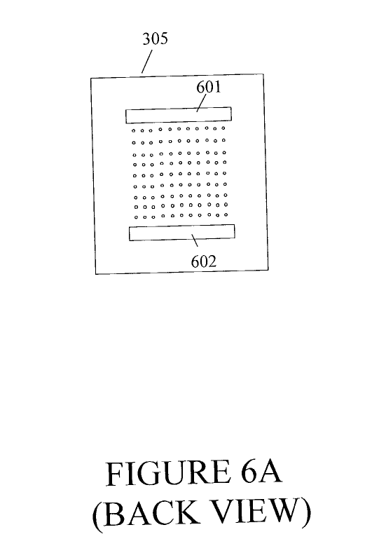

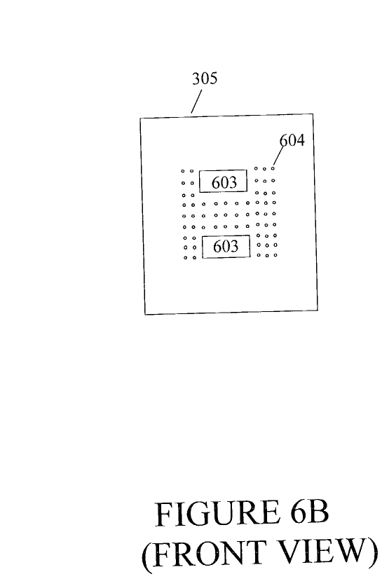

FIG. 6A illustrates an exemplary back view of an embodiment of socket adapter board 305 in accordance with the present invention. Socket adapter board 305 is a circuit board in one embodiment. In one embodiment of its back side, socket adapter board 305 has two connectors 601 and 602 which are positioned and designed to match with connectors 504-505, respectively, on DUT interface board 303. In other words, socket adapter board 305 can be electrically and mechanically connected to DUT interface board 303 through corresponding connector pairs 504-505 and 601-602. Hence, electrical signals can be sent between socket adapter board 305 and DUT interface board 303. Connectors discussed above are well-known to persons of ordinary skill in the art and therefore are not further discussed.

Referring now to FIG. 6B illustrating an exemplary front view of an embodiment of socket adapter board 305. In an embodiment of its front side, socket adapter board 305 has multiple sockets 603 (two are shown in FIG. 6B) plugged into holes 604 of socket adapter board 305. Selected predetermined holes 604 are electrically connected together and/or to selected pins of connectors 601-602, for example through the use of an embedded predetermined metal layer, such that when sockets 603 are plugged into socket adapter board 305, selected pins of sockets 603 and connectors 601-602 are electrically connected (e.g., pins 1 of sockets 603 are connected to pins 15 of connectors 601-602, pins 2 of sockets 603 are connected to pins 6-9 of connectors 601-602, etc.). In another embodiment, the desired electrical connection between corresponding pins of sockets 603 and connectors 601 and 602 is established through electrical wiring the corresponding pins together. Sockets 603 are used to accommodate different DUTs through insertion. By having the ability to accommodate multiple DUTs at the same to be carried out on multiple DUTs at the same time thereby increasing the ATE's efficiency as well as flexibility. Connectors and sockets discussed above are well-known to persons of ordinary skill in the art and therefore are not further discussed.

An embodiment of the present invention, a DUT interface board assembly that can accommodate a plurality of DUTs for testing at any one time, easily and rapidly be configured to provide a plurality of different test functions to the plurality of DUTs at any one time, minimize damages to the test head module and wear-and-tear to its connectors during set up, control external environmental factors which may adversely effects test functions carried out by the DUT interface board, and allow close-coupled instruments to be located in the DUTs proximity has been presented. While the present invention has been described in a particular embodiment, the present invention should not be construed as limited by such an embodiment, but rather construed according to the below claims.

What is claimed is:

1. A Device-Under-Test (DUT) interface assembly to provide an interface between a test head and one or more DUTs, the DUT interface board assembly comprising:
a DUT interface board having one or more receptacles to receive one or more close-coupled instruments, the one or more receptacles provide an electrical connection between the DUT interface board and the one or more close-coupled instruments, the one or more close-coupled instruments are detachable from the DUT interface board; and
an interposer mechanically and electrically connected between the test head and the DUT interface board, the interposer having a cavity to spatially accommodate the one or more close-coupled instruments inserted into the one or more receptacles on the DUT interface board such that when the interposer is attached between the test head and the DUT interface board, the cavity becomes essentially enclosed thereby facilitating controlling of environmental factors inside the enclosed cavity, wherein the DUT interface board is detachable from the interposer;
wherein the DUT interface board in turn is coupled to the one or more DUTs.

2. The DUT interface assembly of claim 1 further comprising an socket adapter for coupling the one or more DUTs to the DUT interface board, the socket adapter is mechanically and electrically connected to the DUT interface board, the socket adapter is detachable from the DUT interface board, the socket adapter having one or more receptacles to connect one or more sockets, the socket adapter providing an electrical connection between the one or more sockets and the DUT interface board, wherein the one or more sockets receive the plurality of DUTs such that the one or more DUTs are located in a proximity of the close-coupled instruments boards and wherein the one or more sockets provides an electrical connection between the plurality of DUTs and the socket adapter.

3. The DUT interface board assembly of claim 1, wherein cool air or an inert gas is forced through the enclosed cavity of the interposer to control temperature.

4. The DUT interface board assembly of claim 1, wherein dry air or inert gas is force through the enclosed cavity of the interposer to control humidity.

5. The DUT interface assembly of claim 1, wherein the enclosed cavity of the interposer provides electrical isolation for noise reduction.

6. The DUT interface board assembly of claim 1, wherein the interposer is an open-ended tubular bracket having four adjoined walls and an interior cavity.

7. The DUT interface board assembly of claim 1, wherein the interposer includes signal conditioning circuitry.

8. The DUT interface board assembly of claim 1, wherein the interposer has a height designed to accommodate a handler or prober interface requirement.

9. The DUT interface assembly of claim 6, wherein the interposer is mechanically and electrically connected to the test head by corresponding connectors so that the interposer is easily detachable from the test head.

10. The DUT interface assembly of claim 1, wherein the DUT interface board is a circuit board.

11. The DUT interface assembly of claim 10, wherein the DUT interface board is mechanically and electrically connected to the interposer by corresponding connectors so that the DUT interface board is easily detachable from the test head.

12. The DUT interface assembly of claim 11, wherein the DUT interface board further comprises a Complex Programmable Logic Device (CPLD) to configure the DUT interface board for a specific test function and memory electrically connected to the CPLD to store configuration parameters for different test functions.

13. The DUT interface assembly of claim 12, wherein the plurality of receptacles of the DUT interface board are connectors.

14. The DUT interface assembly of claim 2, wherein the socket adapter is a circuit board.

15. The DUT interface assembly of claim 14, wherein the socket adapter is mechanically and electrically connected to the DUT interface board by corresponding connectors so that the socket adapter is easily detachable from the DUT interface board.

16. The DUT interface assembly of claim 15, wherein the plurality of receptacles of the socket adapter are holes.

17. An ATE system comprising:
a CPU;
I/O peripherals connected to the CPU;
a remote test head electrically linked to the CPU;
power supplies coupled to the CPU, I/O peripherals, and the test head; and
a Device-Under-Test (DUT) interface assembly to provide an interface between the remote test head and one or more DUTs, the DUT interface assembly comprising:
a DUT interface board having one or more receptacles to receive one or more close-coupled instruments, the one or more receptacles provide an electrical connection between the DUT interface board and the one or more close-coupled instruments, the close-coupled instruments are detachable from the DUT interface board;
an interposer mechanically and electrically connected between the test head and the DUT interface board, the interposer having a cavity to spatially accommodate the plurality of close-coupled instruments inserted into the one or more receptacles on the DUT interface board such that when the interposer is attached between the test head and the DUT interface board, the cavity becomes essentially enclosed thereby facilitating controlling of environmental factors inside the enclosed cavity, wherein the DUT interface board is detachable from the interposer;
wherein the DUT interface board in turn is coupled to the one or more DUTs.

18. The ATE system of claim 17, wherein the DUT interface assembly further comprising an socket adapter for coupling the one or more DUTs to the DUT interface board, the socket adapter is mechanically and electrically connected to the DUT interface board, the socket adapter is detachable from the DUT interface board, the socket adapter having one or more receptacles to connect one or more sockets, the socket adapter providing an electrical connection between the one or more sockets and the DUT interface board, wherein the one or more sockets receive the plurality of DUTs such that the one or more DUTs are located in a proximity of the close-coupled instruments and wherein the one or more sockets provides an electrical connection between the plurality of DUTs and the socket adapter.

19. The ATE system of claim 17, wherein cool air or inert gas is forced through the enclosed cavity of the interposer to control temperature.

20. The ATE system of claim 17, wherein dry air or inert gas is force through the enclosed cavity of the interposer to control humidity.

21. The ATE system of claim 17, wherein the interposer is an open-ended tubular bracket having four adjoined walls and an interior cavity.

22. The ATE system of claim 17, wherein the interposer includes signal conditioning circuitry.

23. The ATE system of claim 17, wherein the interposer has a height designed to accommodate a handler or prober.

24. The ATE system of claim 19, wherein the interposer is mechanically and electrically connected to the test head by corresponding connectors so that the interposer is easily detachable from the test head.

25. The ATE system of claim 17, wherein the DUT interface board is a circuit board and the DUT interface board is mechanically and electrically connected to the interposer by corresponding connectors so that the DUT interface board is easily detachable from the test head.

26. The ATE system of claim 25, wherein the DUT interface board further comprises a Complex Programmable Logic Device (CPLD) to configure the DUT interface board for a specific test function and memory electrically connected to the CPLD to store configuration parameters for different test functions.

27. The ATE system of claim 26, wherein the plurality of receptacles of the DUT interface board are connectors.

28. The ATE system of claim 17, wherein the socket adapter is a circuit board and the socket adapter is mechanically and electrically connected to the DUT interface board by corresponding connectors so that the socket adapter is easily detachable from the DUT interface board.

29. The ATE system of claim 28, wherein the plurality of receptacles of the socket adapter are holes.
